(19) United States
(12) Patent Application Publication
(10) Pub. No.: US 2019/0078196 A1
(43) Pub. Date: Mar. 14, 2019

(54) FILM-FORMING METHOD AND SPUTTERING APPARATUS

(71) Applicant: ULVAC, INC., Kanagawa (JP)

(72) Inventors: Shinya Nakamura, Kanagawa (JP); Mitsunori Henmi, Kanagawa (JP); Yoshinori Fujii, Kanagawa (JP)

(73) Assignee: ULVAC, INC., Kanagawa (JP)

(21) Appl. No.: 15/747,283

(22) PCT Filed: Apr. 4, 2017
(86) PCT No.: PCT/JP2017/014041

§ 371 Date: Jan. 24, 2018

(30) Foreign Application Priority Data
May 23, 2016 (JP) 2016-102631

(51) Int. Cl. C23C 14/34; H01L 21/02; C23C 14/35; C23C 14/54

(52) U.S. Cl. CPC C23C 14/3485; C23C 14/542; C23C 14/351; H01L 21/02266

(57) ABSTRACT

In a film-forming method: a to-be-processed substrate and a target are disposed inside a vacuum chamber; a sputtering gas is introduced into the vacuum chamber; and electric power is charged to the target to sputter the target, thereby forming a film on the surface of the to-be-processed-substrate. A leakage magnetic field is caused to locally act on a lower side of a sputtering surface by means of a magnet unit disposed above the target in case that surface of the target which is sputtered is defined as the sputtering surface and the sputtering-surface side is defined as the lower side. The magnet unit is rotated, during film formation by sputtering, such that a region of action of the leakage magnetic field on the sputtering surface varies continuously. A step is included in which a direction of rotation of the magnet unit in a forward direction and a reverse direction is alternately switched.

### TECHNICAL FIELD

The present invention relates to a film-forming method which comprises; disposing a substrate that is to be processed (to-be-processed substrate) and a target inside a vacuum chamber; introducing a sputtering gas into the vacuum chamber; and charging electric power to the target in order to sputter the target, thereby forming a film on a surface of the to-be-processed substrate, and relates also to a sputtering apparatus.

### BACKGROUND ART

In case a film is formed on the surface of the to-be-processed substrate according to this kind of film-forming method, in order, for example, to increase the utilization efficiency of the target, a leakage magnetic field is caused to locally act on a lower side of a sputtering surface by means of a magnet unit disposed above the target in case that surface of the target which is sputtered is defined as the sputtering surface and the sputtering-surface side is defined as the lower side. The magnet unit is then rotated in one direction, during film formation by sputtering, so that a region of action of the leakage magnetic field on the sputtering surface varies continuously (see, e.g., Patent Document 1). Ordinarily, the direction of rotation of the magnet unit will not be changed until the end of the life end of the target.

By the way, among the targets, there is a so-called sintered target. When this kind of sintered target is used and a plurality of to-be-processed substrates are sequentially subjected to film forming by applying the above-mentioned film-forming method under equivalent film-forming conditions (charged electric power, amount of introduction of the sputtering gas, sputtering time, and the like), it has been found that, with an increase in the integral power consumption to be charged to the target, the film thicknesses of the thin films formed on the surfaces of the to-be-processed substrates vary. In this case, in the process of manufacturing electronic devices, the variation in the film thickness gives an adverse effect on the subsequent steps. It is therefore expected to keep the amount of film thickness variation to the minimum extent possible.

Then, as a result of strenuous efforts and studies made by the inventors of this invention, they have come to obtain a finding that, by changing the direction of rotation of the magnet unit depending on the amount of erosion of the target, the amount of film thickness variation can be minimized to the extent possible. This phenomenon is supposed to be attributable to the fact that, by rotating the magnet unit only in one direction of rotation so that sputtering is continued to the life end of the target, the ions of the sputtering gas get collided to the sputtering surface at the same angle and, consequently, that the target is constantly eroded in the same surface direction.

### PRIOR ART DOCUMENT

### Patent Document

Patent document 1: JP-A-2016-11445

### SUMMARY OF THE INVENTION

### Problems to be Solved by the Invention

On the basis of the above, this invention has a problem of providing a film-forming method and a sputtering apparatus which are capable of minimizing, to the best extent possible, the amount of film thickness variation, even in case continuous film forming is performed on plural numbers of to-be-processed substrates.

### Means for Solving the Problems

In order to solve the above problem, this invention is a film-forming method for forming a film on a surface of a to-be-processed substrate. The method comprises: disposing the to-be-processed substrate and a target inside a vacuum chamber; introducing a sputtering gas into the vacuum chamber; and charging electric power to the target to sputter the target, thereby forming a film on the surface of the to-be-processed-substrate; causing a leakage magnetic field to locally act on a lower side of a sputtering surface by means of a magnet unit disposed above the target in case that surface of the target which is sputtered is defined as the sputtering surface and the sputtering-surface side is defined as the lower side; and rotating the magnet unit, during film formation by sputtering, such that a region of action of the leakage magnetic field on the sputtering surface varies continuously. The method further comprises a step of alternately switching a direction of rotation of the magnet unit into a forward direction or a reverse direction depending on an integral power consumption that is charged to the target.

According to this invention, during the time to the life end of the target, whenever the direction of rotation of the magnet unit is switched depending on the integral power consumption, i.e., depending on the amount of erosion of the target, the angle at which the ions in the sputtering gas get impinged on the sputtering surface varies, and the surface direction in which the target gets eroded varies. Therefore, as a result of erosion of the target in a plurality of surface directions, the amount of film thickness variation can be minimized to the extent possible even in case films are formed in succession on a plurality of to-be-processed substrates.

In this invention the target is a sintered target made of an electrically insulating material. This invention can be suitably applied to a case in which sputtering is performed by charging RF power to the sintered target.

Further, in order to solve the above-mentioned problem, the sputtering apparatus according to this invention comprises: a sputtering power source for charging electric power to a target disposed inside a vacuum chamber; a magnet unit disposed above the target so as to cause to locally act the leakage magnetic field on a lower side of a sputtering surface in case that surface of the target which is sputtered is defined as the sputtering surface and the sputtering-surface side is defined as the lower side; and a driving means for rotating the magnet unit, during film formation by sputtering, such that a region of action of the leakage magnetic field on the sputtering surface varies continuously. The sputtering apparatus further comprises: a rotational direction switching means for switching the direction of rotation of the magnet unit into a forward direction or a reverse direction depending on an integral power consumption that is charged to the target.

According to this invention, by alternately switching the direction of rotation of the magnet unit between the forward direction and the reverse direction depending on the integral power consumption that is charged to the target, the amount of film thickness variation can be minimized to the extent possible even in case film formation is performed in succession on plural number of to-be-processed substrates.

### BRIEF DESCRIPTION OF THE DRAWINGS

FIG. 1 is a schematic sectional view showing the sputtering apparatus for carrying out the film-forming method according to an embodiment of this invention.

FIG. 2 is a schematic plan view to explain the direction of rotation of the magnet unit.

FIG. 3 is a graph to show the results of experiments to confirm the effects of this invention.

FIG. 4 is a graph to show the results of experiments to confirm the effects of this invention.

### MODES FOR CARRYING OUT THE INVENTION

With reference to the drawings description will hereinbelow be made of a film-forming method and a sputtering apparatus according to an embodiment of this invention, with reference to an example in which a to-be-processed substrate W is made of a silicon substrate, and in which an aluminum oxide film is formed on the surface of this silicon substrate.

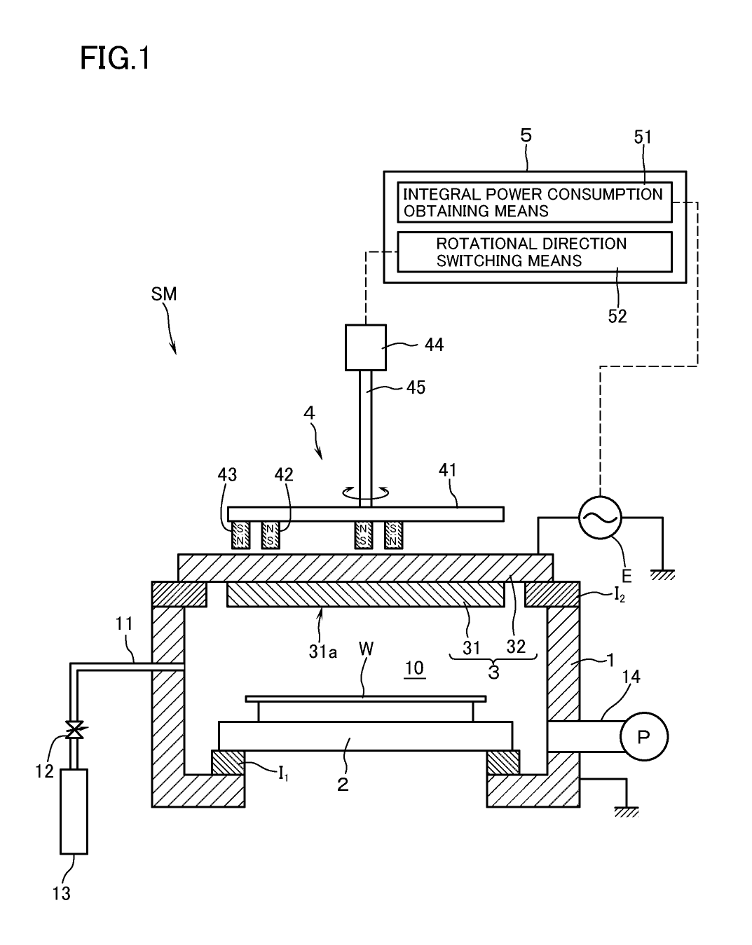

With reference to FIG. 1, reference mark SM denotes a magnetron type of sputtering apparatus. This sputtering apparatus SM is provided with a vacuum chamber 1 which defines a processing chamber 10. To the side wall of the vacuum chamber 1 is connected a gas pipe 11 which introduces a sputtering gas. The gas pipe 11 has interposed therein a mass flow controller 12 which is in communication with a gas source 13. The sputtering gas shall be understood to be composed not only of a rare gas such as argon and the like but also of a reactive gas such as oxygen gas, water vapor, and the like in case the reactive sputtering is performed. The side wall of the vacuum chamber 1 has connected thereto an exhaust pipe 14 which is communicated with vacuum exhausting means P which is made up of a turbo molecular pump, rotary pump, and the like. According to this arrangement, the sputtering gas whose flow rate is controlled by a mass flow controller 12 can be introduced into the processing chamber 10 that has been evacuated by the evacuating means P. During film formation, the pressure in the processing chamber 10 is arranged to be maintained substantially constant.

At a bottom portion of the vacuum chamber 1, there is disposed a substrate stage 2 through an electrically insulating material I₁. The substrate stage 2 has a known electrostatic chuck (not illustrated). By charging electrodes of the electrostatic chuck with chuck voltage from a chuck power source, it is so arranged that the to-be-processed substrate W can be held in position by suction on the stage 2 with the film-forming surface facing up.

The ceiling portion of the vacuum chamber 1 has mounted thereon a target assembly 3. The target assembly 3 is constituted by a sintered target 31 which is made of aluminum oxide and is formed by a known method into a plate shape of a circle as seen from top (plan view) depending on the profile of the to-be-processed target W. In case that surface of the target 31 which is sputtered is defined as a sputtering surface 31a and the sputtering-surface side is defined as a “lower” side, the target assembly 3 is further constituted by a backing plate 32 which is bonded to the upper surface of the target 31 through a bonding material (not illustrated) such as indium, and the like. It is so arranged that, during film formation by sputtering, the target 31 can be cooled by flowing cooling medium (cooling water) through the inside of the backing plate 32. In a state in which the target 31 is mounted in position, the peripheral portion on the lower surface of the backing plate 32 is attached to the upper portion of the side wall of the vacuum chamber 1 through an electrically insulating material 12. The target 31 has connected thereto, through the backing plate 32, an output of the RF power as a sputtering power source E. It is thus so arranged that RF power can be charged to the target 31. It is to be noted that, as the sputtering power source E, without being limited to the RF power, DC power or DC pulse power, and the like may also be used depending on the target 31 to be used.

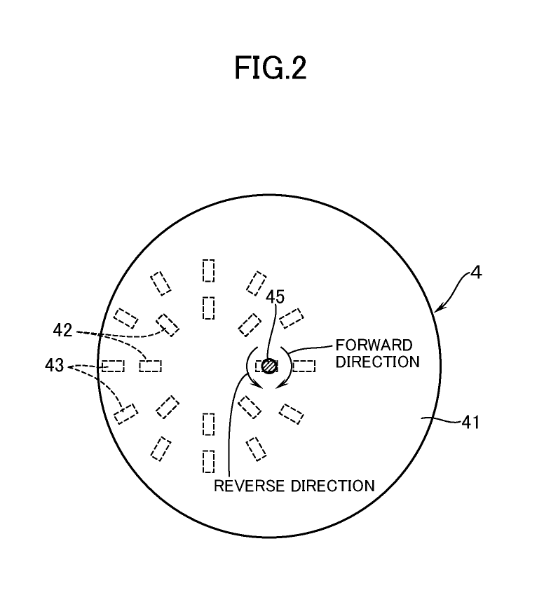

Above the target assembly 3 there is disposed a magnet unit 4. It is thus so arranged: that leakage magnetic field is caused to act locally on the lower side of the sputtering surface 31a of the target 31; that the electrons and the like ionized below the sputtering surface 31a during film formation by sputtering are captured; and that the sputtered particles scattered from the target 31 are efficiently ionized. With reference also to FIG. 2, the magnet unit 4 has: a disk-like yoke 41; a plurality of first magnets 42 that are disposed into an annular shape side by side with one another on the lower surface of the yoke 41; and a plurality of second magnets 43 that are disposed into an annular shape side by side with one another so as to enclose the circumference of the first magnets 42. To the center of the upper surface of the yoke 41, there is connected a rotary shaft 45 of a driving means 44 such as a motor, and the like. It is thus so arranged that, by driving to rotate the rotary shaft 45, the first magnets 42 and the second magnets 43 rotate with the center of the target 31 serving as the center of rotation and, accordingly, that the region of action of the leakage magnetic field on the sputtering surface 31a varies continuously. It is thus so arranged that the direction of rotation of the rotary shaft 45, and consequently of the magnet unit 4, by the driving means 44, can be switched by a rotational direction switching means 52 of a control section 5, which is described hereinafter, between a forward direction and a reverse direction

The above-mentioned sputtering apparatus SM has the control section 5 which is equipped with a microcomputer, sequencer, and the like so that an overall control can be made of: the operation of the mass flow controller 12; the operation of the vacuum exhaust means P; the operation of the sputtering power supply E, and the like. The control section 5 has: an integral power consumption obtaining means 51 for obtaining an integral power consumption (charged power (kW)×time (h)) to be charged from the sputtering power E into the target 31; and the rotational direction switching means 52 for switching over the rotational direction of the magnet unit 4 between a forward direction and a reverse direction depending on the integral power consumption. The integral power consumption obtaining means 51 may obtain the integral power consumption to be inputted from the sputtering power supply E, or may calculate the integral power consumption based on control signals to be outputted to the sputtering power supply E. Description will hereinafter be made of a film-forming method according to an embodiment of this invention by using the above-mentioned sputtering apparatus SM.

First, by using the transfer robot (not illustrated), a to-be-processed substrate W (first substrate) is transferred on to the stage 2, and by means of the stage 2 the to-be-processed substrate W is held in position on the stage 2. Then, by controlling the mass flow controller 12, argon gas is introduced by a predetermined flow rate (e.g., 100˜200 sccm) (the pressure in the processing chamber 10 at this time becomes 1.8˜2.2 Pa). At the same time, RF power is charged from the RF power supply E to the target 31 at, e.g., 13.56 MHz by 2 kW˜5 kW to thereby form plasma inside the vacuum chamber 1 to subject the target 31 to sputtering. By adhering and depositing the sputtered particles, scattered by sputtering, on the surface of the to-be-processed substrate W, aluminum oxide film is formed on the surface of the to-be-processed substrate W. During film formation, by rotating the magnet unit 4 in the forward direction, the region of action of the leakage magnetic field on the sputtering surface 31 is caused to vary continuously.

When a predetermined sputtering time has passed, the introduction of argon gas and the charging of electric power are stopped to thereby finish the film formation. The to-be-processed substrate W that has been processed is transferred from the vacuum chamber 1. Then, the next to-be-processed substrate W (a second substrate) is transferred into the vacuum chamber 1, and the film formation is carried out on the above-mentioned conditions (electric power to be charged, flow rate of the sputtering gas, sputtering time).

By the way, among the above-mentioned targets 31, there are included so-called sintered targets. If film formation is sequentially carried out on a plurality of to-be-processed substrates W by using this kind of sintered targets, there is a problem in that the film thickness of the thin films formed on the surfaces of the to-be-processed substrates W may vary as the integral power consumption charged to the targets increase.

As a solution, in this embodiment, a step is arranged to be included in which the direction of rotation of the magnet unit 4 is alternately switched between the forward direction and the reverse direction depending on the integral power consumption that is charged to the target 31. By performing this step after the film formation on the first substrate, the film formation on the second to-be-processed substrate W will be performed while rotating the magnet unit 4 in the reverse direction of rotation. Here, the expression “depending on the integral power consumption” means that the timing of switching the direction of rotation of the magnet unit 4 can be arbitrarily set. As a result, the switching may be made after having completed the film formation on predetermined number (e.g., one piece) of piece of the to-be-processed substrate W, or else switching may be made when the integral power consumption has reached a predetermined amount. In case the integral power consumption has reached the predetermined amount in the course of film formation, switching may be made as soon as the film formation on the to-be-processed substrate W, now in the course of film formation, has come to an end. Further, in case, e.g., the thickness of the thin film to be formed is large, the film formation on one piece of to-be-processed substrate W will be performed in a plurality of steps (e.g., in 2 steps). In this case, switching may be made between the steps. By the way, once the direction of rotation of the magnet unit 4 has been switched, the integral power consumption may be reset.

As described so far, according to this embodiment, during the time for the target 31 to reach the life end thereof, the direction of rotation of the magnet unit 4 can be alternately switched between the forward direction and the reverse direction depending on the integral power consumption, i.e., the amount of erosion of the target 31. In this manner, each time the direction of rotation is switched, the angle at which the ions of the sputtering gas impinge on the sputtering surface 31a changes and, as a result, the surface direction in which the target 31 gets eroded changes. In this manner, since the target 31 gets eroded in a plurality of surface directions, even in case continuous film formation is performed on a plurality of to-be-processed substrates W, the amount of film thickness variation can be minimized to the best extent possible.

Description has so far been made of an embodiment of this invention, but this invention shall not be limited to the above. In the above-mentioned embodiment, description was made of an example in which an aluminum oxide film was formed by using a target 31 made of aluminum oxide. This invention can similarly be applicable when other thin films are formed by using other sintered targets. Still furthermore, the layout of the magnets 42, 43 which constitute the magnet unit 4 need not be limited to the example shown in FIG. 2, but a known layout may also be employed.

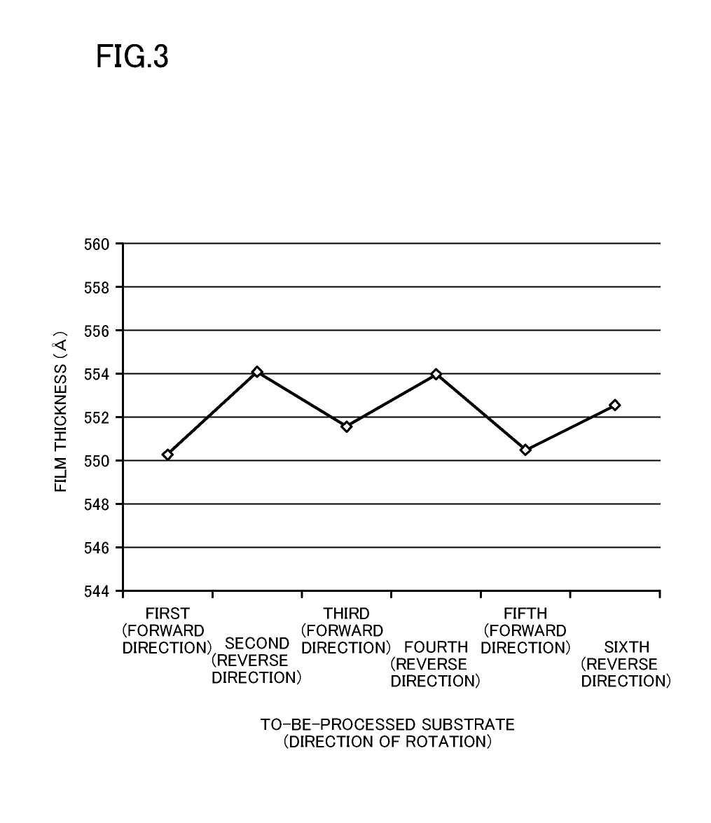

Next, in order to confirm the above-mentioned effects, the following experiments of this invention were carried out by using the above-mentioned sputtering apparatus SM. In these experiments, a silicon substrate of 300 mm Φ (in diameter) was used as the to-be-processed substrate W. After having set in position the to-be-processed substrate W (first substrate) on the stage 2 inside the vacuum chamber 1, argon gas was introduced into the processing chamber 10 at a flow rate of 200 sccm (at this time the pressure inside the processing chamber 10 was about 2.2 Pa). RF power of 13.56 MHz was charged by 4 kW to the target 31 made of aluminum oxide. According to this arrangement, plasma was formed inside the processing chamber 10. While rotating the magnet unit 4 in the forward direction at a speed of 40˜60 rpm, the target 31 was subjected to sputtering. An aluminum oxide film was formed on the surface of the to-be-processed substrate W, and the film thickness of the aluminum oxide film was measured. Except for the fact that the direction of rotation of the magnet unit 4 was alternately switched between the forward direction and the reverse direction with each of the substrates, aluminum oxide films were sequentially formed on the second through the sixth to-be-processed substrates W under the same film-forming conditions as above. The results of measurements of the aluminum oxide films thus continuously formed are shown in FIG. 3. According to this arrangement, the minimum film thickness was about 550 Å and the maximum thickness was about 554 Å. It has thus been confirmed that the amount of film thickness variation can be kept as small as about 4 Å. By the way, in case continuous film formation was performed on 10 pieces of to-be-processed substrates, similar results were obtained. Still furthermore, similar results were obtained when continuous film formation was performed on 15 pieces of to-be-processed substrates by switching the direction of rotation of the magnet unit 4 every 5 pieces of substrates.

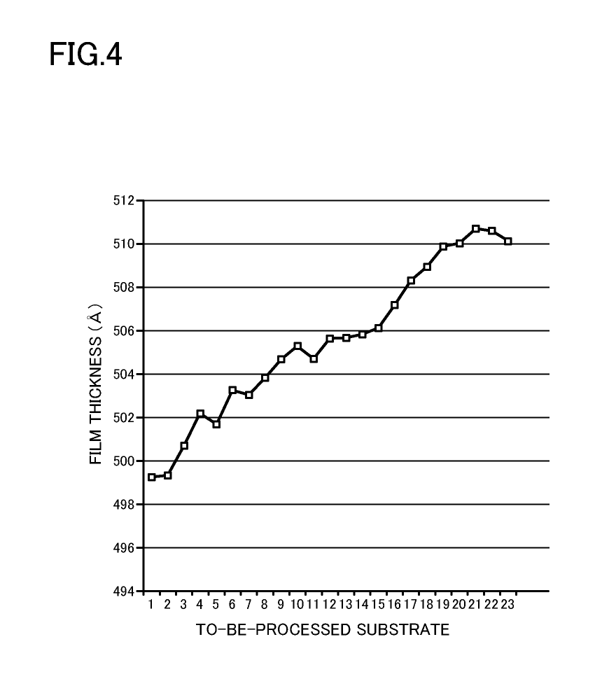

Comparative experiments were carried out relative to the above-mentioned experiments of this invention. FIG. 4 shows the results of the experiments in which the magnet unit 4 was rotated only in the forward direction, in other words, aluminum oxide films were sequentially formed on plural number (23 pieces) of to-be-processed substrates W without alternately switching the direction of rotation of the magnet unit 4. The film thicknesses of the aluminum oxide films that were continuously formed, as measured, are shown in FIG. 4. According to these experiments, the minimum film thickness was about 499 Å and the maximum thickness was about 511 Å. It has thus been confirmed that the amount of film thickness variation was as large as about 12 Å. As a result of these experiments, it has been confirmed that, by switching the direction of rotation of the magnet unit 4 alternately in the forward direction and in the reverse direction, the amount of film thickness variation can be kept as small as possible.

### DESCRIPTION OF REFERENCE MARKS

SM sputtering apparatus
W substrate to be processed (to-be-processed substrate)
1 vacuum chamber
31 target (sintered target)
31a sputtering surface
4 magnet unit
44 driving means
52 rotational direction switching means

What is claimed is:

1. A film-forming method for forming a film on a surface of a to-be-processed substrate, the method comprising:
disposing the to-be-processed substrate and a target inside a vacuum chamber;
introducing a sputtering gas into the vacuum chamber; and
charging electric power to the target to sputter the target, thereby forming a film on the surface of the to-be-processed-substrate;
causing a leakage magnetic field to locally act on a lower side of a sputtering surface by means of a magnet unit disposed above the target in case that surface of the target which is sputtered is defined as the sputtering surface and the sputtering-surface side is defined as the lower side; and
rotating the magnet unit, during film formation by sputtering, such that a region of action of the leakage magnetic field on the sputtering surface varies continuously,
wherein the method further comprises a step of alternately switching a direction of rotation of the magnet unit into a forward direction or a reverse direction depending on an integral power consumption that is charged to the target.

2. The film-forming method according to claim 1,
wherein the target is a sintered target made of an electrically insulating material; and
wherein RF power is charged to the sintered target.

3. A sputtering apparatus comprising:
a sputtering power source for charging electric power to a target disposed inside a vacuum chamber;
a magnet unit disposed above the target so as to cause to locally act the leakage magnetic field on a lower side of a sputtering surface in case that surface of the target which is sputtered is defined as the sputtering surface and the sputtering-surface side is defined as the lower side; and
a driving means for rotating the magnet unit, during film formation by sputtering, such that a region of action of the leakage magnetic field on the sputtering surface varies continuously;
wherein the sputtering apparatus further comprises:
a rotational direction switching means for switching the direction of rotation of the magnet unit into a forward direction or a reverse direction depending on an integral power consumption that is charged to the target.
